(19) United States
(12) Patent Application Publication
(10) Pub. No.: US 2026/0060050 A1
(43) Pub. Date: Feb. 26, 2026

(54) SEMICONDUCTOR DEVICE AND METHOD OF FORMING THEREOF

(71) Applicant: TAIWAN SEMICONDUCTOR MANUFACTURING COMPANY, LTD., Hsinchu (TW)

(72) Inventors: Cheng-I LIN, Hsinchu (TW); Cheng-Yu WEI, Taoyuan City (TW); Shu-Han CHEN, Hsinchu City (TW); Chi On CHUI, Hsinchu City (TW)

(73) Assignee: TAIWAN SEMICONDUCTOR MANUFACTURING COMPANY, LTD., Hsinchu (TW)

(21) Appl. No.: 18/815,652

(22) Filed: Aug. 26, 2024

(51) Int. Cl. H01L 21/762; H01L 29/06; H01L 29/423; H01L 29/66; H01L 29/775; H01L 29/786

(52) U.S. Cl. CPC H01L 21/76224; H10D 30/014; H10D 30/43; H10D 30/6735; H10D 30/6757; H10D 62/121; H10D 64/017

(57) ABSTRACT

A method of forming a semiconductor device includes a number of operations. A first semiconductor fin and a second semiconductor fin is formed over a substrate. An isolation region is formed between the first semiconductor fin and the second semiconductor fin. A first passivation layer is formed over the isolation region. A gate structure is formed over the first passivation layer.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 17 illustrate cross-section views of forming a semiconductor structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The present disclosure is generally related to integrated circuit (IC) structures and methods of forming the same, and more particularly to fabricating gate-all-around (GAA) transistors. It is also noted that the present disclosure presents embodiments in the form of multi-gate transistors. Multi-gate transistors include those transistors whose gate structures are formed on at least two-sides of a channel region. These multi-gate devices may include a p-type metal-oxide-semiconductor device or an n-type metal-oxide-semiconductor device. Specific examples may be presented and referred to herein as FinFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), and/or other suitable channel configuration. Presented herein are embodiments of devices that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices that may benefit from aspects of the present disclosure.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Various embodiments of the present disclosure relate to a nanosheet semiconductor device structure having passivation layers as protection hard masks over isolation oxide. In the gate replacement (RPG) process, etching step(s) may potentially damage the oxide material in the shallow trench isolation (STI) regions. Such damage can lead to dishing or voids in the oxide material in the STI regions, which may degrade device performance or increase the risk of leakage current between metal gates. To mitigate this issue, the present disclosure in various embodiments provides additional passivation layers over the oxide material in the STI regions. The passivation layers masks serve to shield the STI regions from damage during etching step(s) in the RPG process. In some embodiments, the passivation layers are formed over a dielectric layer used as the dummy dielectric layer in a RPG loop, so that the dielectric layer and the passivation layers may protect the STI regions. In some embodiments, the passivation layers and the dielectric layers may protect the nanosheet to reduce loss of the nanosheet in the RPG loop.

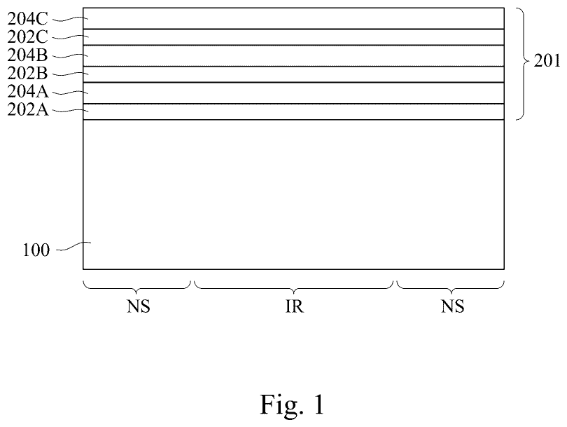

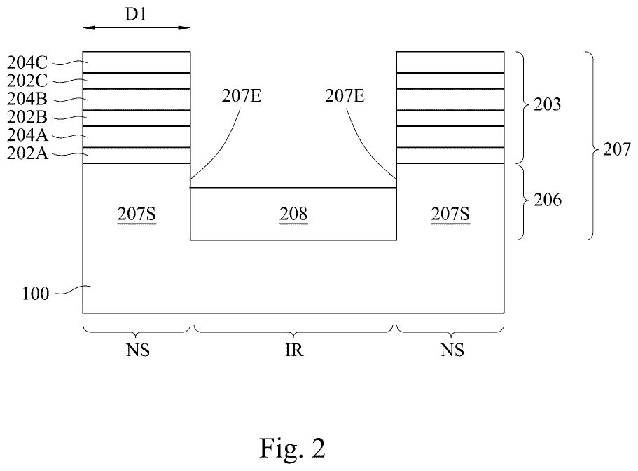

Reference is made to FIGS. 1 through 11. FIGS. 1 through 11 illustrate cross-sectional views of forming a semiconductor device 200, in accordance with some embodiments. FIGS. 1 through 11 illustrate the cross-sectional views along a longitudinal axis of the nanostructures 203 as described in FIG. 2, in accordance with some embodiments.

FIG. 1 illustrates a cross-sectional view of forming a multi-layer stack 201 over a substrate 100, in accordance with some embodiments.

In FIG. 1, a substrate 100 is provided. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Further in FIG. 1, a multi-layer stack 201 is formed over the substrate 100. The multi-layer stack 201 includes alternating layers of first semiconductor layers 202A-C (collectively referred to as first semiconductor layers 202) and second semiconductor layers 204A-C (collectively referred to as second semiconductor layers 204). For purposes of illustration and as discussed in greater detail below, the first semiconductor layers 202 will be removed and the second semiconductor layers 204 will be patterned to form channel regions of GAA-FETs.

The multi-layer stack 201 is illustrated as including three layers of each of the first semiconductor layers 202 and the second semiconductor layers 204 for illustrative purposes. In some embodiments, the multi-layer stack 201 may include any number of the first semiconductor layers 202 and the second semiconductor layers 204. Each of the layers of the multi-layer stack 201 may be epitaxially grown using a process such as chemical vapor deposition (CVD), atomic layer deposition (ALD), vapor phase epitaxy (VPE), molecular beam epitaxy (MBE), or the like. In various embodiments, the second semiconductor layers 204 may be formed of a semiconductor material suitable for serving as channel regions of GAA-FETs, such as silicon, silicon carbon, silicon germanium, or the like.

The first semiconductor materials and the second semiconductor materials may be materials having a high-etch selectivity to one another. As such, the first semiconductor layers 202 of the first semiconductor material may be removed without significantly removing the second semiconductor layers 204 of the second semiconductor material, thereby allowing the second semiconductor layers 204 to serve as channel regions of GAA-FETs.

Reference is made to FIG. 2 to illustrate a cross-sectional view of forming a fin structure 206 in the substrate 100 and forming nanostructures over the fin structure 206, in accordance with some embodiments. FIG. 2 further illustrates forming an isolation region 208 over the substrate 100.

As illustrated in FIG. 2, fin structures 206 are formed in the substrate 100 and nanostructures 203 are formed in the multi-layer stack 201, in accordance with some embodiments. Each fin structure 206 and its overlying nanostructures 203 can be collectively referred to as a semiconductor fin 207 each having longest sides 207S extending along a longitudinal or lengthwise direction D1, and longitudinal ends 207E spaced apart along the longitudinal direction D1. In some embodiments, the nanostructures 203 and the fin structures 206 may be formed in the multi-layer stack 201 and the substrate 100, respectively, by etching trenches in the multi-layer stack 201 and the substrate 100. Each fin structure 206 and overlying nanostructures 203 can be collectively referred to as a semiconductor fin extending from the substrate 100. The etching may be any acceptable etch process, such as a reactive ion etch (RIE), neutral beam etch (NBE), the like, or a combination thereof. The etching may be anisotropic. Forming the nanostructures 203 by etching the multi-layer stack 201 may further define first nanostructures 202A-C (collectively referred to as the first nanostructures 202) from the first semiconductor layers 202 and define second nanostructures 204A-C (collectively referred to as the second nanostructures 204) from the second semiconductor layers 204. The first nanostructures 202 and the second nanostructures 204 may further be collectively referred to as nanostructures 203.

The fin structures 206 and the nanostructures 203 may be patterned by any suitable method. For example, the fin structures 206 and the nanostructures 203 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 206. While each of the fin structures 206 and the nanostructures 203 are illustrated as having a consistent width throughout, in other embodiments, the fin structures 206 and/or the nanostructures 203 may have tapered sidewalls such that a width of each of the fin structures 206 and/or the nanostructures 203 continuously increases in a direction towards the substrate 100. In such embodiments, each of the nanostructures 203 may have a different width and be trapezoidal in shape.

As illustrated in FIG. 2, a shallow trench isolation (STI) region 208 is formed between longitudinal ends 207E of adjacent the fin structures 206. The STI region 208 may be an isolation structure formed between the fin structures 206. The STI regions 208 may be formed by depositing an insulation material over the substrate 100, the fin structures 206, and nanostructures 203, and between adjacent fin structures 206. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 203. Although the insulation material is illustrated as a single layer, some embodiments may utilize multiple layers. For example, in some embodiments a liner (not separately illustrated) may first be formed along a surface of the substrate 100, the fin structures 206, and the nanostructures 203. Thereafter, a fill material, such as those discussed above may be formed over the liner.

A removal process is then applied to the insulation material to remove excess insulation material over the nanostructures 203. In some embodiments, a planarization process such as a chemical mechanical polish (CMP), an etch-back process, combinations thereof, or the like may be utilized. The planarization process exposes the nanostructures 203 such that top surfaces of the nanostructures 203 and the insulation material are level after the planarization process is complete.

The insulation material is then recessed to form the STI region 208. The insulation material is recessed such that upper portions of fin structures 206 protrude from between neighboring STI regions 208. Further, the top surfaces of the STI regions 208 may have a flat surface as illustrated, a convex surface, a concave surface (such as dishing), or a combination thereof. The top surfaces of the STI regions 208 may be formed flat, convex, and/or concave by an appropriate etch. The STI regions 208 may be recessed using an acceptable etching process, such as one that is selective to the material of the insulation material (e.g., etches the material of the insulation material at a faster rate than the material of the fin structures 206 and the nanostructures 203). For example, an oxide removal using, for example, dilute hydrofluoric (dHF) acid may be used.

The process described above with respect to FIGS. 1 and 2 is just one example of how the fin structures 206 and the nanostructures 203 may be formed. In some embodiments, the fin structures 206 and/or the nanostructures 203 may be formed using a mask and an epitaxial growth process. For example, a dielectric layer can be formed over a top surface of the substrate 100, and trenches can be etched through the dielectric layer to expose the underlying substrate 100. Epitaxial structures can be epitaxially grown in the trenches, and the dielectric layer can be recessed such that the epitaxial structures protrude from the dielectric layer to form the fin structures 206 and/or the nanostructures 203. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Further in FIG. 2, appropriate wells (not separately illustrated) may be formed in the fin structures 206 and/or the nanostructures 203. In some embodiments with different well types in different device regions (e.g., NFET region and PFET region), different implant steps may be achieved using a photoresist or other masks (not separately illustrated). For example, a photoresist may be formed over the fin structures 206 and the STI regions 208 in the NFET region and the PFET region. The photoresist is patterned to expose the PFET region. The photoresist can be formed by using a spin-on technique and can be patterned using acceptable photolithography techniques. Once the photoresist is patterned, a first impurity (e.g., n-type impurity such as phosphorus, arsenic, antimony, or the like) implant is performed in the PFET region, and the photoresist may act as a mask to substantially prevent the first impurities from being implanted into the NFET region. After the implant, the photoresist is removed, such as by an acceptable ashing process.

Following or prior to the implanting of the PFET region, a photoresist or other masks (not separately illustrated) is formed over the fin structures 206, the nanostructures 203, and the STI regions 208 in the NFET region and the PFET region. The photoresist is then patterned to expose the NFET region. The photoresist can be formed by using a spin-on technique and can be patterned using acceptable photolithography techniques. Once the photoresist is patterned, a second impurity (e.g., p-type impurity such as boron, boron fluoride, indium, or the like) implant may be performed in the NFET region, and the photoresist may act as a mask to substantially prevent p-type impurities from being implanted into the PFET region. After the implant, the photoresist may be removed, such as by an acceptable ashing process.

After one or more well implants of the NFET region and PFET region, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

As illustrated in FIG. 2, after the fin structures 206, the nanostructures 203 and the STI REGION 208 are formed, the substrate 100 may include nanostructure regions NS and an isolation region IR. The fin structures 206 and the nanostructures 203 are formed in the nanostructure regions NS. The STI REGION 208 is formed in the isolation region IR. In FIG. 2, the isolation region IR is between the two immediately-adjacent nanostructures NS.

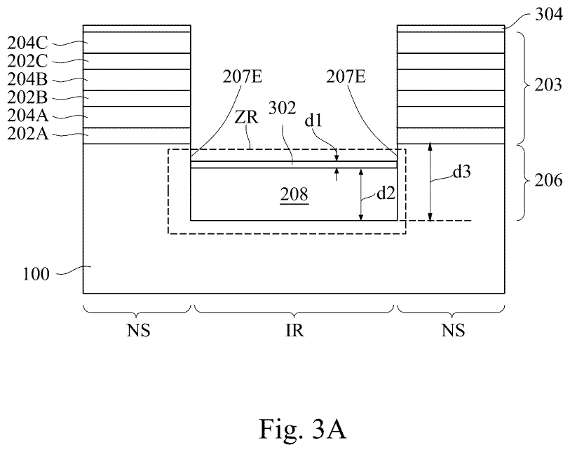

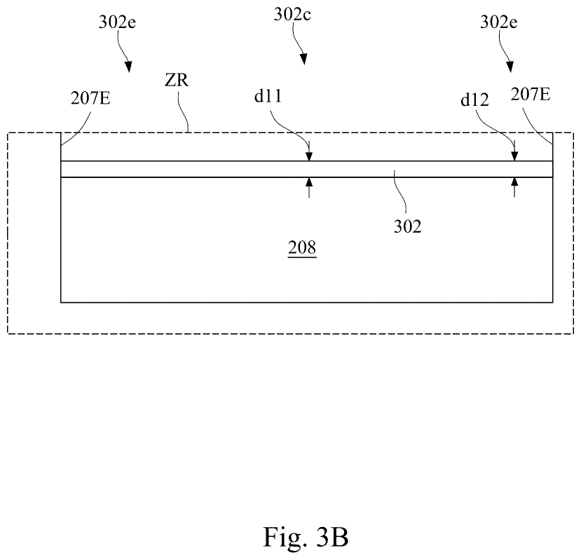

Reference is made to FIG. 3A. FIG. 3A illustrates a cross-sectional view of selectively forming passivation layers 302 and 304 over the structure as illustrated in FIG. 2.

As illustrated in FIG. 3A, the passivation layer 302 is formed over a top surface of the STI region 208, and the passivation layer 304 are formed over top surfaces of the topmost nanostructures 204C. Sidewalls of the nanostructures 203 are exposed between the passivation layers 302 and 304. In one or more embodiments of the present disclosure, the passivation layers 302 and 304 may be formed by a deposition process such as a physical vapor deposition (PVD) process or an anisotropic plasma-enhanced atomic layer deposition (PEALD) process with a bias function. The deposition direction of the passivation layers 302 and 304 can be controlled to ensure selective deposition on the top surfaces of the STI region 208 and the nanostructures 204C, while avoiding deposition on the sidewalls of the nanostructures 203. In one or more embodiments of the present disclosure, the passivation layers 302 and 304 may include SiCₓ, SiOₓC_{y}N_{1-x-y} SiOCx or compounds of precursors such as bis(diethylamino)silane (SiH₂(NEt₂)₂, SAM 24) or N, N-diisopropylaminosilane (DIPAS, LTO520).

Selective deposition of the passivation layers 302, 304 can be achieved through several mechanisms inherent to the chosen deposition techniques. In some embodiments of PVD, the process involves the physical ejection of material from a target source, which then condenses onto the substrate 100. By carefully controlling the angle of incidence and the energy of the ejected particles, it is feasible to deposit material on horizontal surfaces (such as the top surfaces of the STI region 208 and nanostructures 204C) while minimizing deposition on vertical sidewalls. This is due to the line-of-sight nature of PVD, where particles travel in relatively straight paths and are less likely to deposit on the sidewalls unless they are directly exposed.

For anisotropic PEALD with a bias function, the example process involves alternating exposure to a precursor gas and a plasma, which facilitates the deposition of thin films with atomic-level precision. The bias function can be used to create an electric field that directs the plasma ions predominantly towards the horizontal surfaces. This anisotropic behavior allows that the ions have a higher probability of interacting with and depositing on the top surfaces rather than the sidewalls. Furthermore, the use of a bias function in PEALD can enhance the directionality of the ion flux, effectively steering the ions towards the desired deposition areas. By adjusting the bias voltage and plasma parameters, the deposition process can be finely tuned to achieve the desired selectivity. This precise control over the deposition environment allows for the formation of passivation layers 302 and 304 with minimal or no material on the sidewalls of the nanostructures 203.

Reference is made to FIG. 3A. The passivation layer 302 has a thickness d1. The STI region 208 has a thickness d2. A distance d3 is measured from a level of a bottommost surface of the STI region 208 to a bottom surface of the first semiconductor layers 202A. Stated another way, the distance d3 is the height of fin structure 206. In some embodiments, a ratio of the thickness d1 of the passivation layer 302 to the thickness d2 of the STI region 208 may be in a range from about 0.013 to about 0.12. In some embodiments, a ratio of the thickness d1 of the passivation layer 302 to the distance d3 may be in a range from about 0.125 to about 0.1. In some embodiments, a ratio of the thickness d2 of the STI region 208 to the distance d3 may be in a range from about 0.03 to about 0.25.

FIG. 3B is a zoom-in cross-sectional view of a partial region ZR of FIG. 3A, wherein the partial region ZR is near the top surface of the STI region 208, and the passivation layer 302 between the longitudinal ends 207E of the fin structures 206 is illustrated. As illustrated in FIG. 3B, in some embodiments, the passivation layer 302 may include edge portions 302e near the opposite longitudinal ends 207E of the fin structures 206 and a center portion 302c between the edge portions 302e. The center portion 302c of the passivation layer 302 may have a thickness d11. The edge portions 302e may have a thickness d12. In some embodiments, the thickness d11 of the center portion 302c may be roughly equal to the thickness d12 of the edge portions 320e, and thus the passivation layer 302 may have a linear top surface and have a uniform thickness d2 as illustrated in FIG. 3A. In some embodiments, the passivation layer 302 may have a non-linear top surface due to the selective deposition, and the thickness d11 of the center portion 302c may be different from the thickness d12 of the edge portions 320e. For example, in some embodiments, during the selective deposition of the passivation layer 302, a deposition rate of the passivation layer 302 near the opposite longitudinal ends 207E of the fin structures 206 is less than a deposition rate of the passivation layer 302 on the center of the STI region 208, so that a thickness d12 of the edge portions 302e is less than a thickness d11 of the center portion 302c. In some embodiments, a difference between the thickness d11 of the center portion 302c and the thickness of the edge portions 302e may be in a range from about 10 Å to about 20 Å. Therefore, in some embodiments, the passivation layer 302 may have the thick center portion 302c and the thin edge portions 302e.

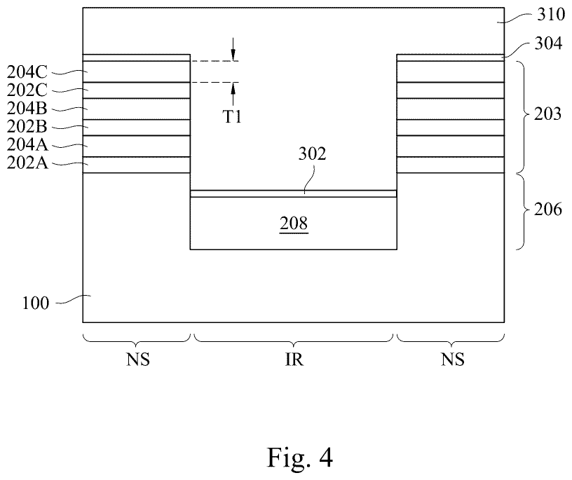

Reference is made to FIG. 4. FIG. 4 illustrates a cross-sectional view of forming a sacrificial layer 310 over the passivation layer 302 over the STI region 208 and the passivation layers 304 over the nanostructures 204C. In FIG. 4, the sacrificial layer 310 is filled with the recess between the fin structures 206. In one or more embodiments of the present disclosure, the sacrificial layer 310 may be an oxide material such as SiOₓ, and may be deposited by any suitable method, such as CVD, plasma-enhanced CVD (PECVD), or FCVD. In FIG. 4, the top surface of the sacrificial layer 310 is higher than the passivation layers 302 and 304.

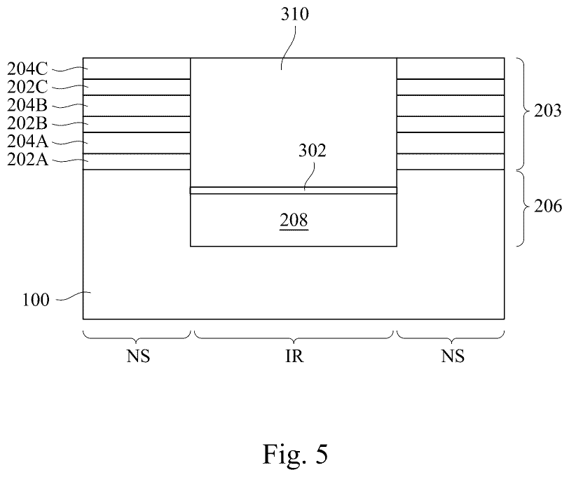

FIG. 5 illustrates a cross-sectional view of performing a planarization process to the structure as illustrated in FIG. 4, in accordance with some embodiments. As illustrated in FIG. 5, the planarization process, such as a CMP, may be performed to level the top surface of the sacrificial layer 310 with the top surfaces of the nanostructures 204C. The planarization process may also remove the passivation layers 304 on the top surfaces of the nanostructures 204. After the planarization process, top surfaces of the sacrificial layer 310 and the nanostructures 204C are level within process variations. Accordingly, the top surfaces of the nanostructures 204C are exposed through the sacrificial layer 310. The passivation layer 302 remains between the STI region 208 and the sacrificial layer 310.

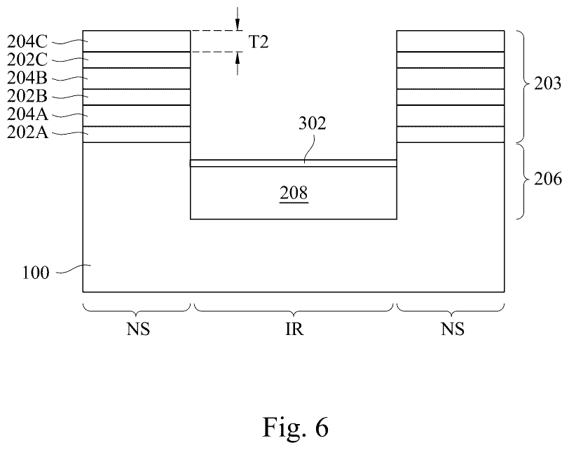

Continuing to FIG. 5, FIG. 6 illustrates removing the sacrificial layer 310. In some embodiments, the sacrificial layer 310 may be removed by a wet etching process. After removing the sacrificial layer, the passivation layer 302 is exposed from the fin structures 206, and the sidewalls of the nanostructures 203 and the fin structure 206 are exposed. In some embodiments, the sacrificial layer 310 may be oxide materials, and the passivation layer 302 may protect the STI region 208 during removing the sacrificial layer 310.

Reference is made to FIGS. 4 and 6. In some embodiments, the nanostructures 204C have a thickness T1 prior to performing the planarization process to the nanostructures 204C as illustrated in FIG. 4, and the nanostructures 204C have a thickness T2 after performing the planarization process to the nanostructures 204C. The thickness T1 may be greater than the thickness T2. In some embodiments, the thickness T1 may be greater than a thickness of each of the nanostructures 204A and 204B, so that the thickness T2 of the nanostructures 204C may be substantially equal to the thickness of each of the nanostructures 204A and 204B after performing the planarization process to the nanostructures 204C.

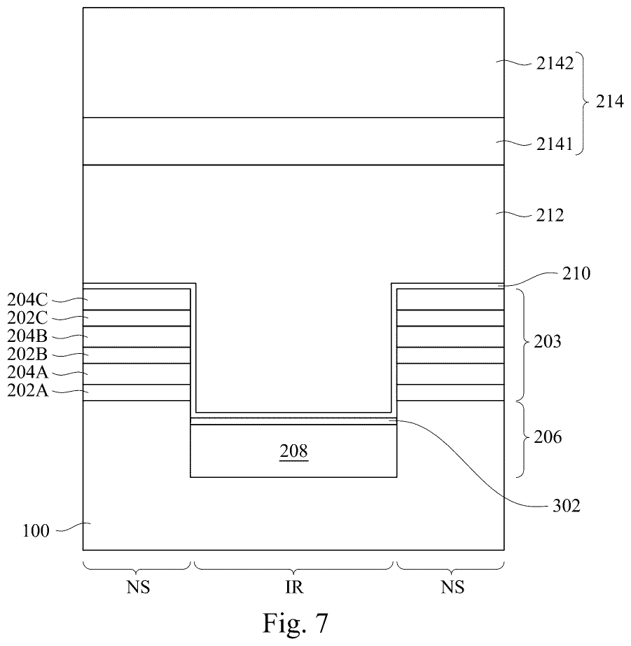

Reference is made to FIG. 7. FIG. 7 illustrates forming a dummy dielectric layer 210 over the passivation layer 302, the exposed inner sidewall of the nanostructures 203 and the top surfaces of the topmost nanostructures 204C. FIG. 7 further illustrates forming a dummy gate layer 212 and mask layers 214 including mask layers 2141 and 2142 over the dummy dielectric layer 210.

As illustrated in FIG. 7, the dummy dielectric layer 210 is formed along the passivation layer 302, the exposed inner sidewall of the nanostructures 203 and the top surfaces of the topmost nanostructures 204C. The dummy dielectric layer 210 may be, for example, silicon oxide, silicon nitride, a combination thereof, or the like, and may be deposited or thermally grown according to acceptable techniques. A dummy gate layer 212 is formed over the dummy dielectric layer 210, and a mask layer 214 is formed over the dummy gate layer 212. The dummy gate layer 212 may be deposited over the dummy dielectric layer 210 and then planarized, such as by a CMP. The mask layers 2141 and 2142 of the mask layer 214 may be deposited over the dummy gate layer 212. The dummy gate layer 212 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 212 may be deposited by physical vapor deposition (PVD), CVD, sputter deposition, or other techniques for depositing the selected material. The dummy gate layer 212 may be made of other materials that have a high etching selectivity from the etching of the STI region 208. The mask layers 214a and 2142 of the mask layers 214 may include, for example, silicon nitride, silicon oxynitride, or the like.

It is noted that the dummy dielectric layer 210 is shown covering the fin structures 206 and the nanostructures 203 for illustrative purposes only. In some embodiments, the dummy dielectric layer 210 may be deposited such that the dummy dielectric layer 210 covers the STI regions 208, such that the dummy dielectric layer 210 extends between the dummy gate layer 212 and the STI regions 208.

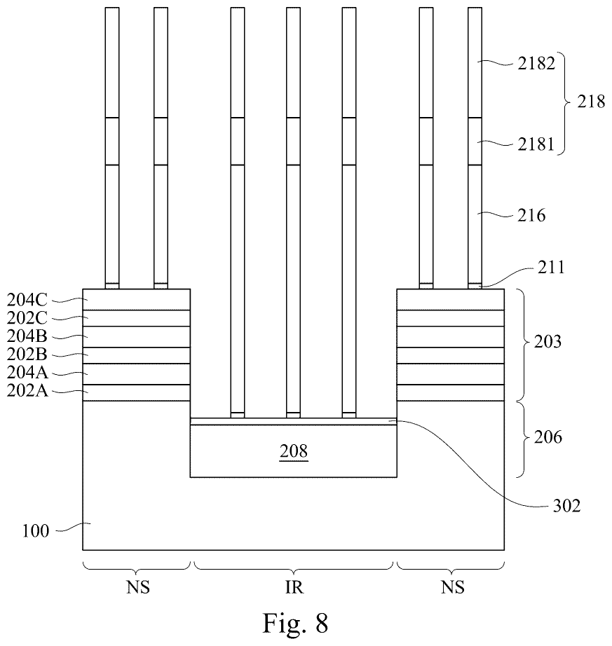

Reference is made to FIG. 8. FIG. 8 illustrates forming a dummy gate layer 214 and a mask 218 including mask layers 2181 and 2182 by patterning the dummy gate layer 212 and the mask layers 2141 and 2142 of the mask layers 214, in accordance with some embodiments.

As illustrated in FIG. 8, the mask layers 2141 and 2142 of the mask layer 214 may be patterned using acceptable photolithography and etching techniques to form masks 218 including masks 2181 and 2182. The pattern of the masks 218 then may be transferred to the dummy gate layer 212 and to the dummy dielectric layer 210 to form dummy gates 216 and dummy gate dielectrics 211, respectively. The dummy gates 216 cover respective channel regions of the fin structures 206. The pattern of the masks 218 may be used to physically separate each of the dummy gates 216 from adjacent dummy gates 216. The dummy gates 216 may also have a lengthwise direction substantially perpendicular to the lengthwise direction of respective fin structures 206. The dummy dielectrics 211 in the isolation region IR is lower than the dummy dielectrics 211 in the nanostructure regions NS. The dummy dielectrics 211 in the isolation region IR are formed between the STI region 208 and the passivation layer 302.

In FIG. 8, the dummy gate dielectrics 211 are directly between the nanostructures 204C and the dummy gates 216 in the nanostructure region NS, and the dummy gate dielectrics 211 are directly between the passivation layer 302 over the STI region 208 and the dummy gates 216 in the isolation region IR. The passivation layer 302 may be served as a protection hard mask over the STI region 208 and used to protect the STI region 208 during removing the dummy dielectrics 211.

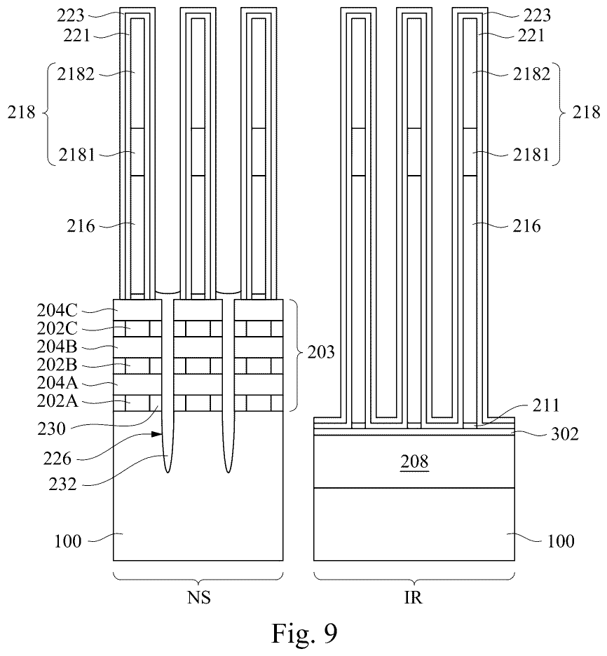

Reference is made to FIG. 9. FIG. 9 illustrates forming a first spacer layer 221 and a second spacer layer 223 over the dummy gate structure including the masks 218, the dummy gates 216 and the dummy dielectric s 211, in accordance with some embodiments. FIG. 9 illustrates cross-sectional views of the nanostructure region NS and the isolation region IR along a longitudinal axis of the nanostructures 203.

As illustrated in FIG. 9, a first spacer layer 221 and a second spacer layer 223 are formed over the structures illustrated in FIG. 8. The first spacer layer 221 and the second spacer layer 223 will be subsequently patterned to act as spacers for forming self-aligned source/drain regions.

In some embodiments, the first spacer layer 221 is formed on top surfaces of the passivation layer 302 over the STI regions 208, the inner sidewalls of the fin structures 206 and the nanostructures 203, the top surfaces of nanostructures 204C, sidewalls of the dummy gate dielectrics 211 and the dummy gates 216 and top surfaces and sidewalls of the masks 218 including the mask layers 2181 and 2182. The first spacer layer 221 may be formed of silicon oxide, silicon nitride, silicon oxynitride, or the like, using techniques such as thermal oxidation or deposited by CVD, ALD, or the like. The second spacer layer 223 may be formed of a material having a different etch rate than the material of the first spacer layer 223, such as silicon oxide, silicon nitride, silicon oxynitride, or the like, and may be deposited by CVD, ALD, or the like.

In FIG. 9, the first spacer layer 221 and the second spacer layer 223 are etched to form first spacers 221 and second spacers 223. As will be discussed in greater detail below, the first spacers 221 and the second spacers 223 act to self-align subsequently formed source and drain regions (collectively referred to as source/drain regions), as well as to protect sidewalls of the fin structures 206 and/or nanostructure 203 during subsequent processing. The first spacer layer 221 and the second spacer layer 223 may be etched using a suitable etching process, such as an isotropic etching process (e.g., a wet etching process), an anisotropic etching process (e.g., a dry etching process), or the like. In some embodiments, the material of the second spacer layer 223 has a different etch rate than the material of the first spacer layer 221, such that the first spacer layer 221 may act as an etch stop layer when patterning the second spacer layer 223 and such that the second spacer layer 223 may act as a mask when patterning the first spacer layer 221. For example, the second spacer layer 223 may be etched using an anisotropic etch process wherein the first spacer layer 221 acts as an etch stop layer, wherein remaining portions of the second spacer layer 223 form second spacers 223 as illustrated in FIG. 9. Thereafter, the second spacers 223 acts as a mask while etching exposed portions of the first spacer layer 221, thereby forming first spacers 221 as illustrated in the nanostructure region NS of FIG. 9.

As illustrated in FIG. 9, the first spacers 221 and the second spacers 223 are disposed on sidewalls of the fin structures 206 and/or nanostructures 203. In some embodiments, the spacers 221 and 223 only partially remain on sidewalls of the fin structures 206. In some embodiments, no spacer remains on sidewalls of the fin structures 206. In some embodiments, the second spacer layer 223 may be removed from over the first spacer layer 221 adjacent the masks 218, the dummy gates 216, and the dummy gate dielectrics 211, and the first spacers 221 are disposed on sidewalls of the masks 218, the dummy gates 216, and the dummy dielectric layers 211. In some embodiments, a portion of the second spacer layer 223 may remain over the first spacer layer 221 adjacent the masks 218, the dummy gates 216, and the dummy gate dielectrics 211.

In some embodiments, the first spacers 221 on gate sidewalls (also called gate spacers) have a small thickness (e.g., in a range from about 1 nm to about 10 nm) so as to reduce gate-to-gate pitch without significant reduction in source/drain region size. In some embodiments, the first spacers 221 on gate sidewalls is formed of as low-dielectric constant (low-k) materials (e.g., porous silicon oxide) having a k-value, for example, less than about 3.5. The low-k material can aid in reducing parasitic capacitance between, for example, the subsequently formed metal gates and source/drain contacts.

The above disclosure generally describes a process of forming spacers. Other processes and sequences may be used. For example, fewer or additional spacers may be utilized, different sequence of steps may be utilized (e.g., the first spacers 221 may be patterned prior to depositing the second spacer layer 223), additional spacers may be formed and removed, and/or the like.

In FIG. 9, source/drain recesses 226 are formed in the fin structures 206, the nanostructures 203, and the substrate 100, in accordance with some embodiments. The source/drain recess 226 is formed in the nanostructure region NS.

Epitaxial source/drain regions will be subsequently formed in the source/drain recesses 226. The source/drain recesses 226 may extend through the first nanostructures 202 and the second nanostructures 204, and into the substrate 100. In some other embodiments, the fin structures 206 may be etched such that bottom surfaces of the source/drain recesses 226 are disposed below the top surfaces of the STI regions 208, or above the top surfaces of the STI regions 208. The source/drain recesses 226 may be formed by etching the fin structures 206, the nanostructures 203, and the substrate 100 using anisotropic etching processes, such as RIE, NBE, or the like. The first spacers 221, the second spacers 223, and the masks 218 mask portions of the fin structures 206, the nanostructures 203, and the substrate 100 during the etching processes used to form the source/drain recesses 226. A single etch process or multiple etch processes may be used to etch each layer of the nanostructures 203 and/or the fin structures 206. Timed etch processes may be used to stop the etching of the source/drain recesses 226 after the source/drain recesses 226 reach a target depth.

After the source/drain recess 226 are formed, portions of sidewalls of the layers of the nanostructures 203 formed of the first semiconductor materials (e.g., the first nanostructures 202) exposed by the source/drain recesses 226 are etched to form sidewall recesses between corresponding second nanostructures 204. Sidewalls of the first nanostructures 202 in recesses can be straight, concave or convex. The sidewalls may be etched using isotropic etching processes, such as wet etching or the like. In some embodiments in which the first nanostructures 202 include, e.g., SiGe, and the second nanostructures 204 include, e.g., Si or SiC, a dry etch process with tetramethylammonium hydroxide (TMAH) , ammonium hydroxide (NH₄OH), or the like may be used to etch sidewalls of the first nanostructures 202.

In FIG. 9, inner spacers 230 are formed in the sidewall recesses of the nanostructures 202. The inner spacers 230 may be formed by depositing an inner spacer layer (not separately illustrated) in the sidewall recesses of the nanostructures 202 and over the sidewall of the nanostructures 204. The inner spacers 230 act as isolation features between subsequently formed source/drain regions and gate structure. As will be discussed in greater detail below, source/drain regions will be formed in the source/drain recesses 226, and the first nanostructures 202 will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 230. Although outer sidewalls of the inner spacers 230 are illustrated as being flush with sidewalls of the second nanostructures 204, the outer sidewalls of the inner spacers 230 may extend beyond or be recessed from sidewalls of the second nanostructures 204.

In FIG. 9, epitaxial source/drain regions 232 are formed in the source/drain recesses 226. In some embodiments, the source/drain regions 232 may exert stress on the second nanostructures 204, thereby improving device performance. As illustrated in FIG. 9, the epitaxial source/drain regions 232 are formed in the source/drain recesses 226 such that each dummy gate 216 and each passivation layer 302 remaining in the nanostructure region NS are disposed between respective neighboring pairs of the epitaxial source/drain regions 232. In some embodiments, the first spacers 221 are used to separate the epitaxial source/drain regions 232 from the dummy gates 216, and the inner spacers 230 are used to separate the epitaxial source/drain regions 232 from the first nanostructures 202 by an appropriate lateral distance so that the epitaxial source/drain regions 232 do not short out with subsequently formed gates of the resulting GAA-FETs.

In some embodiments, the epitaxial source/drain regions 232 may include any acceptable material appropriate for n-type GAA-FETs. For example, if the second nanostructures 204 are silicon, the epitaxial source/drain regions 232 may include materials exerting a tensile strain on the second nanostructures 204, such as silicon carbide, phosphorous doped silicon carbide, silicon phosphide, or the like. In some embodiments, the epitaxial source/drain regions 232 may include any acceptable material appropriate for p-type GAA-FETs. For example, if the second nanostructures 204 are silicon, the epitaxial source/drain regions 232 may comprise materials exerting a compressive strain on the second nanostructures 204, such as silicon germanium, boron doped silicon germanium, germanium, germanium tin, or the like. The epitaxial source/drain regions 232 may have surfaces raised from respective upper surfaces of the nanostructures 203 and may have facets.

The epitaxial source/drain regions 232 may be implanted with dopants to form source/drain regions, followed by an anneal. The source/drain regions may have an impurity concentration of between about 1×10¹⁷ atoms/cm³ and about 1×10²² atoms/cm³. The n-type and/or p-type impurities for source/drain regions may be any of the impurities previously discussed. In some embodiments, the epitaxial source/drain regions 232 may be in situ doped during growth.

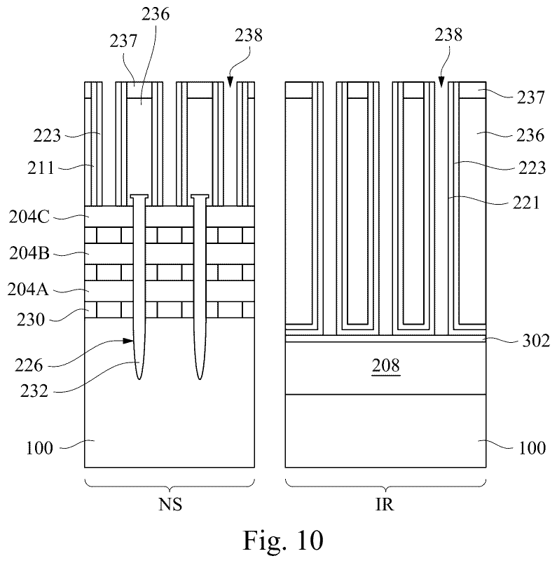

Reference is made to FIG. 10. FIG. 10 illustrates forming an interlayer dielectric layer 236 over the source/drain regions 232 and between the first spacer layers 221 and the second spacer layers 223. FIG. 10 illustrates cross-sectional views of the nanostructure region NS and the isolation region IR along a longitudinal axis of the nanostructures 203.

As illustrated in FIG. 10, an ILD layer 236 is deposited over the structure illustrated in FIG. 9. The ILD layer 236 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) is disposed between the ILD layer 236 and the epitaxial source/drain regions 232, the masks 218, and the first spacers 221. The CESL may include a dielectric material, such as, SiN, SiOₓ, SiCN, SiON, SiOCN, Al₂O₃, HfO₂, ZrO₂, HfAlOₓ, and HfSiOₓ, or the like, having a different etch rate than the material of the overlying ILD layer 236.

After the ILD layer 236 is formed, a planarization process, such as a CMP, may be performed to level the top surface of the ILD layer 236 with the top surfaces of the dummy gates 216 or the masks 218. The planarization process may also remove the masks 218 on the dummy gates 216, and portions of the first spacers 221 along sidewalls of the masks 218. After the planarization process, top surfaces of the dummy gates 216, the first spacers 221, and the ILD layer 236 are level within process variations. Accordingly, the top surfaces of the dummy gates 216 may be exposed through the ILD layer 236. In some embodiments, the masks 218 may remain, in which case the planarization process levels the top surface of the ILD layer 236 with top surface of the masks 218 and the first spacers 221.

As illustrated in FIG. 10, the ILD layer 236 is etched back to fall below the dummy gates 216, and then a protective layer 237 is formed over the ILD layer 236. The protective layer 237 has a higher etch resistance to a following metal gate etch back (MGEB) process than that of the ILD layer 236, and thus the protective layer 237 can serve to protect the underlying ILD layer 236 from potential loss or damage caused by the following MGEB process. The protective layer 237 can be formed by, for example, depositing a layer of dielectric material globally over the substrate 100, followed by performing a planarization process, such as CMP, on the deposited layer of dielectric material until the dummy gates 216 get exposed. In some embodiments, the ILD layer 236 is an oxide-based dielectric material (e.g., silicon oxide), and the protective layer 237 is a nitride-based dielectric material (e.g., silicon nitride).

In FIG. 10, the dummy gates 216, and the masks 218 if present, are removed in one or more etching steps, so that gate trenches 238 are formed between corresponding gate spacers 221. In some embodiments, portions of the dummy gate dielectrics 211 in the gate trenches 238 are also be removed. In some embodiments, the dummy gates 216 and the dummy gate dielectrics 211 are removed by an anisotropic dry etch process. For example, the etching process may include a dry etch process using reaction gas(es) that selectively etch the dummy gates 216 at a faster rate than the protective layer 237 or the first spacers 221. In some embodiments, the removal process to the dummy gate dielectrics 211 of oxide may include, f or example, an oxide removal wet etching process using dilute hydrofluoric (dHF) acid. Each gate trench 238 exposes and/or overlies portions of nanostructures 204, which will serve as channel regions in subsequently completed GAA-FETs. The nanostructures 204 serving as the channel regions are disposed between neighboring pairs of the epitaxial source/drain regions 232. During the removal, the dummy dielectric layers 211 may be used as etch stop layers when the dummy gates 216 are etched. The dummy dielectric layers 211 may then be removed after the removal of the dummy gates 216.

In some embodiments, the dummy dielectrics 211 may be oxide material such as silicon oxide and the STI region 208 may also include oxide material. In one or more embodiments of the present disclosure, the passivation layer 302 are formed between the dummy dielectrics 211 and the STI region 208 before removing the dummy dielectrics 211, so that the passivation layer 302 may be a carbon-containing protection layer protecting the STI region 208 when removing the dummy dielectrics 211. Therefore, selectively forming the passivation layer 302 on the top surface of STI region 208 can reduce the risk of device degradation and metal gate line-to-line leakage, and it effective to prevent damage to the STI region 208 after oxide removal process for removing the dummy dielectrics 211 in replacement gate (RPG) loop and the risk of device degradation and the metal gate line-to-line leakage can be reduced.

As illustrated in FIG. 10, the first nanostructures 202 in the gate trenches are removed by an isotropic etching process such as wet etching or the like using etchants which are selective to the materials of the first nanostructures 202. Stated differently, the first nanostructures 202 are removed by using a selective etching process that etches the first nanostructures 202 at a faster etch rate than it etches the second nanostructures 204, thus forming spaces between the second nanostructures 204 (also referred to as sheet-to-sheet spaces if the nanostructures 204 are nanosheets). This step can be referred to as a channel release process. At this interim processing step, the spaces between second nanostructures 204 may be filled with ambient environment conditions (e.g., air, nitrogen, etc). In some embodiments, the second nanostructures 204 can be referred to as nanosheets, nanowires, nanoslabs, nanorings having nano-scale size (e.g., a few nanometers), depending on their geometry. For example, in some embodiments the second nanostructures 204 may be trimmed to have a substantial rounded shape (i.e., cylindrical) due to the selective etching process for completely removing the first nanostructures 202. In that case, the resultant second nanostructures 204 can be called nanowires.

In embodiments in which the first nanostructures 202 include, e.g., SiGe, and the second nanostructures 204 include, e.g., Si or SiC, tetramethylammonium hydroxide (TMAH), ammonium hydroxide (NH₄OH) or the like may be used to remove the first nanostructures 202. In some embodiments, both the channel release step and the previous step of laterally recessing first nanostructures 202 use a selective etching process that etches first nanostructures 202 (e.g., SiGe) at a faster etch rate than etching second nanostructures 204 (e.g., Si), and therefore these two steps may use the same etchant chemistry in some embodiments. In this case, the etching time/duration of channel release step is longer than the etching time/duration of the previous step of laterally recessing first nanostructures 202, so as to completely remove the sacrificial nanostructures 202.

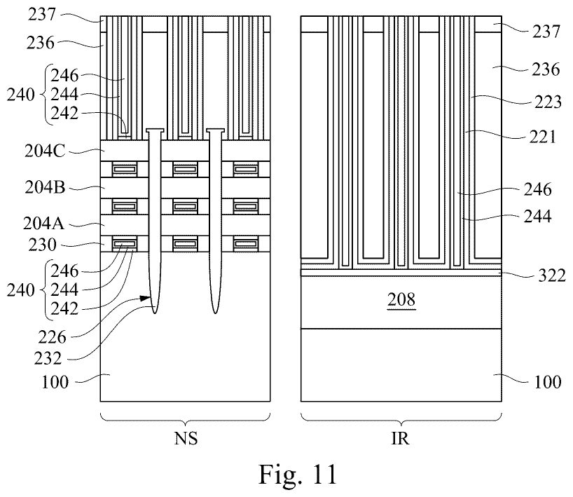

Continuing to FIG. 10, FIG. 11 illustrates forming replacement gate structures 240 in the gate trenches 238. FIG. 11 illustrates cross-sectional views of the nanostructure region NS and the isolation region IR along a longitudinal axis of the nanostructures 203.

In FIG. 11, replacement gate structures 240 are respectively formed in the gate trenches 238 to surround each of the nanosheets 204 suspended in the gate trenches 238. The gate structures 240 may be final gates of GAA FETs. The final gate structure may be a high-k/metal gate stack, however other compositions are possible. In some embodiments, each of the gate structures 240 forms the gate associated with the multi-channels provided by the plurality of nanosheets 204. For example, high-k/metal gate structures 240 are formed within the sheet-to-sheet spaces provided by the release of nanosheets 204. In various embodiments, the high-k/metal gate structure 240 includes an interfacial layer 242 formed around the nanosheets 204, a high-k gate dielectric layer 244 formed around the interfacial layer 242, and a gate metal layer 246 formed around the high-k gate dielectric layer 244 and filling a remainder of gate trenches 238. Formation of the high-k/metal gate structures 240 may include one or more deposition processes to form various gate materials, followed by a CMP process to remove excessive gate materials, resulting in the high-k/metal gate structures 240 having top surfaces level with a top surface of the protective layer 237. As illustrated in the cross-sectional view of FIG. 11, the high-k/metal gate structure 240 surrounds each of the nanosheets 204, and thus is referred to as a gate of a GAA FET.

In some embodiments, the interfacial layer 242 is silicon oxide formed on exposed surfaces of semiconductor materials in the gate trenches 238 by using, for example, thermal oxidation, chemical oxidation, wet oxidation or the like. As a result, surface portions of the nanosheets 204 exposed in the gate trenches 238 are oxidized into silicon oxide to form interfacial layer 242.

In some embodiments, the high-k gate dielectric layer 244 includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO) , zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 246 includes one or more metal layers. For example, the gate metal layer 246 may include one or more work function metal layers stacked one over another and a fill metal filling up a remainder of gate trenches 238. The one or more work function metal layers in the gate metal layer 246 provide a suitable work function for the high-k/metal gate structures 240. For an n-type GAA FET, the gate metal layer 246 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type GAA FET, the gate metal layer 246 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 246 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

As illustrated in FIG. 11, a semiconductor device 200 is provided. In one or more embodiments of the present disclosure, the semiconductor device 200 may include the nanostructures 204A-C as channel regions, the gate structures 240 wrapping around the nanostructures 204A-C and the source/drain regions 232 on opposite sides of the nanostructures 204A-C. The semiconductor device 200 may include the passivation layer 302. In the isolation region IR, the gate structures 240 extend over the passivation layer 302. In some embodiments, the passivation layer 302 may be a carbon-containing protection layer over the STI region 208. The passivation layer 302 may protect the STI region 208 during RPG loop. The ILD layers 236 are formed over the source/drain regions 232. In the nanostructure region NS, the nanostructures 204A-C, the gate structure 240 and the source/drain regions 232 may form transistors over the substrate 100.

It is noted that the gate structure 240 over the passivation layer 302 on the STI region 208 may be a gate structure wrapping around the channel regions in a nanostructure region NS. On the other hands, in some embodiments, each gate structure 240 may have a first portion directly over the passivation layer 302 in one of the isolation regions IR and a second portion between the spacer layers 221 in one of the nanostructure regions NS in a direction perpendicular to the longitudinal axis of the nanostructures 203.

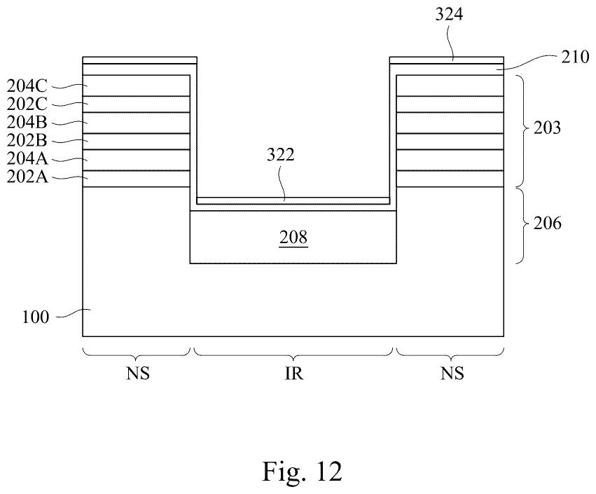

Reference is made to FIGS. 1, 2 and 12 through 17. FIGS. 1, 2 and 12 through 17 illustrate cross-sectional views of forming a semiconductor device 200′, in accordance with some embodiments. FIGS. 12 through 17 illustrate the cross-sectional views along a longitudinal axis of the nanostructures 203 as described in FIG. 2, in accordance with some embodiments.

Continuing to FIG. 2, FIG. 12 illustrates forming a dummy dielectric layer 210 along the top surface of the STI region 208, the exposed inner sidewall of the nanostructures 203 and the top surfaces of the topmost nanostructures 204C. In some embodiments, the dummy dielectric layer 210 may be, for example, silicon oxide, silicon nitride, a combination thereof, or the like, and may be deposited or thermally grown according to acceptable techniques.

FIG. 12 further illustrates forming a protection hard mask 322 is formed over the dummy dielectric layer 210 on the STI region 208 in the isolation region IR and protection hard masks 324 over the dummy dielectric layer 210 on the nanostructure regions NS. In some embodiments, the protection hard mask 322 and the protection hard mask 322 may be carbon-containing passivation layer. The inner sidewalls of the dummy dielectric layer 210 are exposed. In one or more embodiments of the present disclosure, the protection hard masks 322 and 324 may be formed by a deposition process such as a physical vapor deposition (PVD) process or an anisotropic plasma-enhanced atomic layer deposition (PEALD) process with a bias function. The deposition direction of the protection hard masks 322 and 324 can be controlled so that the protection hard masks 322 and 324 can be selectively deposited over the top surfaces of the dummy dielectric layer 210 on the STI region 208 and the nanostructures 204C and not over the sidewalls of the dummy dielectric layer 210 on the nanostructures 203. In some embodiments, the protection hard masks 322 and 324 may include of low-k dielectric materials such as AlOx, SiCx, SiCxN1−x, SiOxCyN_{1-x-y}, SiNₓ or other suitable low-k films. Other details regarding the selective deposition are described previously with respect to the passivation layers 302, 304, and thus they are not repeated for the sake of brevity.

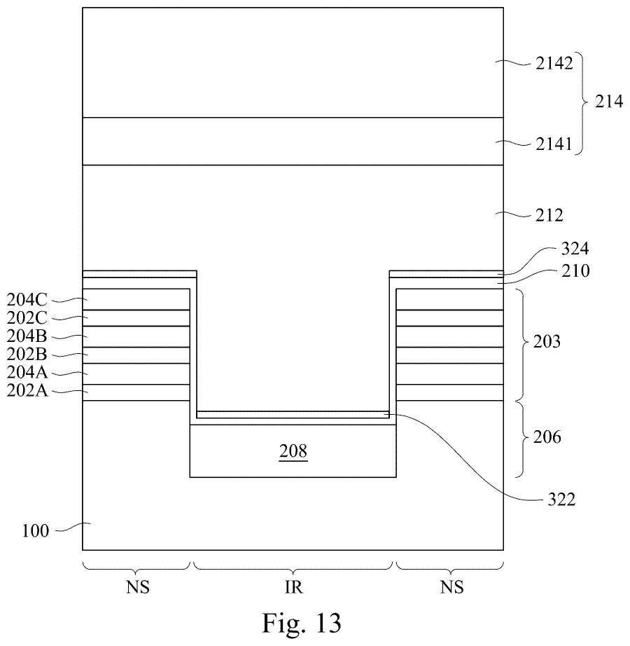

FIG. 13 illustrates a cross-sectional view of forming a dummy gate layer 212 over the protection hard masks 322 and 324 and forming a mask layer 214 over the dummy gate layer 212, in accordance with some embodiments. As illustrated in FIG. 13, in some embodiments, the dummy gate layer 212 may be deposited over the dummy dielectric layer 210 and then planarized, such as by a CMP. The mask layers 2141 and 2142 of the mask layer 214 may be deposited over the dummy gate layer 212. The dummy gate layer 212 may be deposited by physical vapor deposition (PVD), CVD, sputter deposition, or other techniques for depositing the selected material. The dummy gate layer 212 may be made of other materials that have a high etching selectivity from the etching of the STI region 208. The mask layers 2141 and 2142 of the mask layers 214 may include, for example, silicon nitride, silicon oxynitride, or the like.

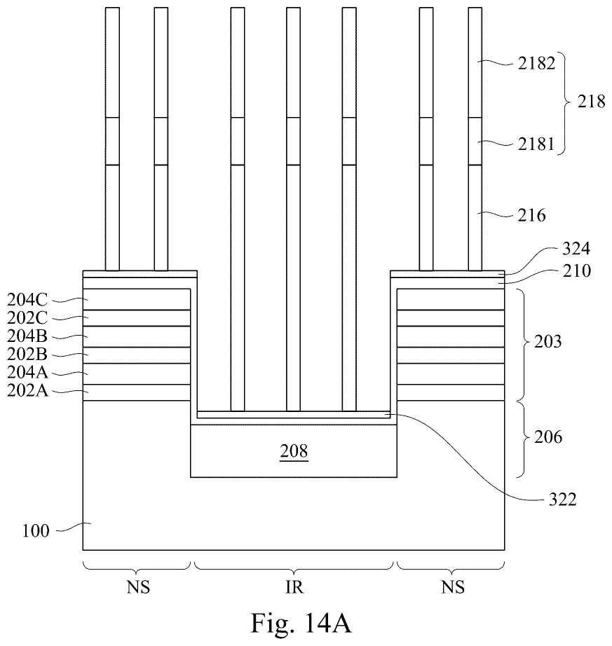

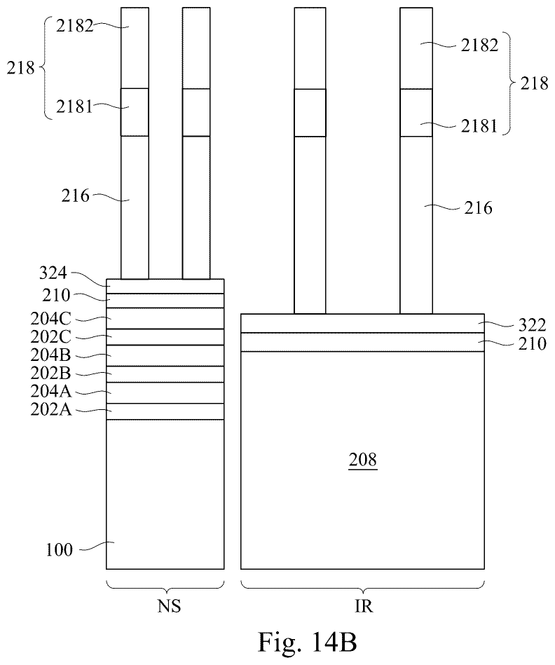

Reference is made to FIGS. 14A and 14B. FIGS. 14A and 14B illustrates forming dummy gates 216 and masks 218 including mask layers 2181 and 2182 by patterning the dummy gate layer 212 and the mask layers 2141 and 2142 of the mask layers 214, in accordance with some embodiments. FIG. 14B illustrates cross-sectional views of the nanostructure region NS and the isolation region IR along a longitudinal axis of the nanostructures 203 in FIG. 14A.

As illustrated in FIGS. 14A and 14B, the mask layers 2141 and 2142 of the mask layer 214 may be patterned using acceptable photolithography and etching techniques to form masks 218 including masks 2181 and 2182. The pattern of the masks 218 then may be transferred to the dummy gate layer 212 to form dummy gates 216. Horizontal portions of the dummy dielectric layer 210 is covered by the protection hard masks 322 or 324 so that the dummy dielectric layer 210 is not patterned, as illustrated in FIGS. 14A and 14B. The dummy gates 216 cover respective channel regions of the fin structures 206. The pattern of the masks 218 may be used to physically separate each of the dummy gates 216 from adjacent dummy gates 216. The dummy gates 216 may also have a lengthwise direction substantially perpendicular to the lengthwise direction of respective fin structures 206.

In some embodiments, the dummy gate layer 212 may be deposited over the dummy dielectric layer 210 and then planarized, such as by a CMP. The mask layers 2141 and 2142 of the mask layer 214 may be deposited over the dummy gate layer 212. The dummy gate layer 212 may be deposited by physical vapor deposition (PVD), CVD, sputter deposition, or other techniques for depositing the selected material. The dummy gate layer 212 may be made of other materials that have a high etching selectivity from the etching of the STI region 208. The mask layers 214a and 2142 of the mask layers 214 may include, for example, silicon nitride, silicon oxynitride, or the like.

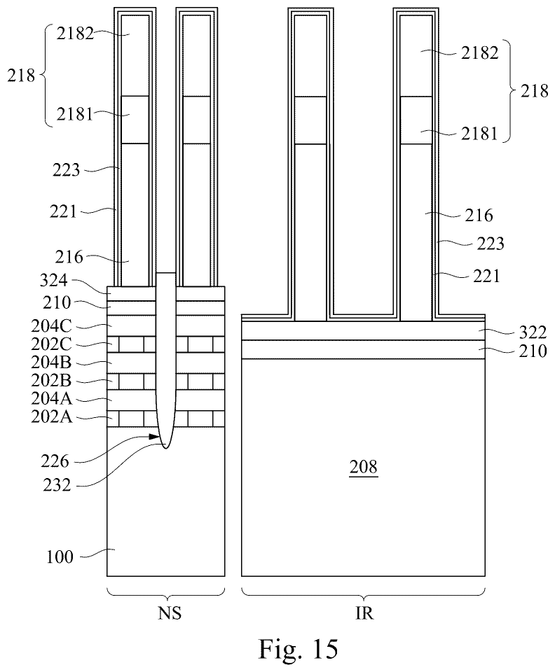

Reference is made to FIG. 15. FIG. 15 illustrates cross-sectional views of the nanostructure region NS and the isolation region IR along a longitudinal axis of the nanostructures 203. As illustrated in FIG. 15, a first spacer layer 221 and a second spacer layer 223 are formed over the structures illustrated in FIGS. 14A and 14B. The first spacer layer 221 and the second spacer layer 223 will be subsequently patterned to act as spacers for forming self-aligned source/drain regions.

In some embodiments, the first spacer layer 221 is formed on top surfaces of the protection hard masks 322 and 324 over the dummy dielectrics layer 210, the inner sidewalls of the fin structures 206 and the nanostructures 203, the top surfaces of the protection hard mask 324 over the nanostructures 204C, sidewalls of the dummy gates 216 and top surfaces and sidewalls of the masks 218 including the mask layers 2181 and 2182. The first spacer layer 221 may be formed of silicon oxide, silicon nitride, silicon oxynitride, or the like, using techniques such as thermal oxidation or deposited by CVD, ALD, or the like. The second spacer layer 223 may be formed of a material having a different etch rate than the material of the first spacer layer 223, such as silicon oxide, silicon nitride, silicon oxynitride, or the like, and may be deposited by CVD, ALD, or the like.

In FIG. 15, source/drain recesses 226 are formed in the fin structures 206, the nanostructures 203, and the substrate 100, in accordance with some embodiments. The source/drain recess 226 is formed in the nanostructure region NS.

Epitaxial source/drain regions will be subsequently formed in the source/drain recesses 226. As illustrated in the nanostructure region in FIG. 15, the source/drain recesses 226 may extend through the dummy dielectric layer 210, the protection hard mask 322, the first nanostructures 202 and the second nanostructures 204, and into the substrate 100. In some other embodiments, the fin structures 206 may be etched such that bottom surfaces of the source/drain recesses 226 are disposed below the top surfaces of the STI regions 208, or above the top surfaces of the STI regions 208. The source/drain recesses 226 may be formed by etching the fin structures 206, the nanostructures 203, and the substrate 100 using anisotropic etching processes, such as RIE, NBE, or the like. The first spacers 221, the second spacers 223, and the masks 218 mask portions of the dummy dielectric layer 210, the protection hard mask 322, the fin structures 206, the nanostructures 203, and the substrate 100 during the etching processes used to form the source/drain recesses 226. A single etch process or multiple etch processes may be used to etch each layer of the nanostructures 203 and/or the fin structures 206. Timed etch processes may be used to stop the etching of the source/drain recesses 226 after the source/drain recesses 226 reach a target depth.

After the source/drain recess 226 are formed, portions of sidewalls of the layers of the nanostructures 203 formed of the first semiconductor materials (e.g., the first nanostructures 202) exposed by the source/drain recesses 226 are etched to form sidewall recesses between corresponding second nanostructures 204. Sidewalls of the first nanostructures 202 in recesses can be straight, concave or convex. The sidewalls may be etched using isotropic etching processes, such as wet etching or the like. In some embodiments in which the first nanostructures 202 include, e.g., SiGe, and the second nanostructures 204 include, e.g., Si or SiC, a dry etch process with tetramethylammonium hydroxide (TMAH) , ammonium hydroxide (NH₄OH), or the like may be used to etch sidewalls of the first nanostructures 202.

Inner spacers 230 are formed in the sidewall recesses of the nanostructures 202. The inner spacers 230 may be formed by depositing an inner spacer layer (not separately illustrated) in the sidewall recesses of the nanostructures 202 and over the sidewall of the nanostructures 204. The inner spacers 230 act as isolation features between subsequently formed source/drain regions and gate structure. As will be discussed in greater detail below, source/drain regions will be formed in the source/drain recesses 226, and the first nanostructures 202 will be replaced with corresponding gate structures. In some embodiments, the inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 230. Although outer sidewalls of the inner spacers 230 are illustrated as being flush with sidewalls of the second nanostructures 204, the outer sidewalls of the inner spacers 230 may extend beyond or be recessed from sidewalls of the second nanostructures 204.

In FIG. 15, epitaxial source/drain regions 232 are formed in the source/drain recesses 226. In some embodiments, the source/drain regions 232 may exert stress on the second nanostructures 204, thereby improving device performance. As illustrated in FIG. 15, the epitaxial source/drain regions 232 are formed in the source/drain recesses 226 such that each dummy gate 216 and each protection hard mask 324 remaining in the nanostructure region NS are disposed between respective neighboring pairs of the epitaxial source/drain regions 232. In some embodiments, the first spacers 221 are used to separate the epitaxial source/drain regions 232 from the dummy gates 216, and the inner spacers 230 are used to separate the epitaxial source/drain regions 232 from the first nanostructures 202 by an appropriate lateral distance so that the epitaxial source/drain regions 232 do not short out with subsequently formed gates of the resulting GAA-FETs.

In some embodiments, the epitaxial source/drain regions 232 may include any acceptable material appropriate for n-type GAA-FETs. For example, if the second nanostructures 204 are silicon, the epitaxial source/drain regions 232 may include materials exerting a tensile strain on the second nanostructures 204, such as silicon carbide, phosphorous doped silicon carbide, silicon phosphide, or the like. In some embodiments, the epitaxial source/drain regions 232 may include any acceptable material appropriate for p-type GAA-FETs. For example, if the second nanostructures 204 are silicon, the epitaxial source/drain regions 232 may comprise materials exerting a compressive strain on the second nanostructures 204, such as silicon germanium, boron doped silicon germanium, germanium, germanium tin, or the like. The epitaxial source/drain regions 232 may have surfaces raised from respective upper surfaces of the nanostructures 203 and may have facets.

The epitaxial source/drain regions 232 may be implanted with dopants to form source/drain regions, followed by an anneal. The source/drain regions may have an impurity concentration of between about 1×10¹⁷ atoms/cm³ and about 1×10²² atoms/cm³. The n-type and/or p-type impurities for source/drain regions may be any of the impurities previously discussed. In some embodiments, the epitaxial source/drain regions 232 may be in situ doped during growth.

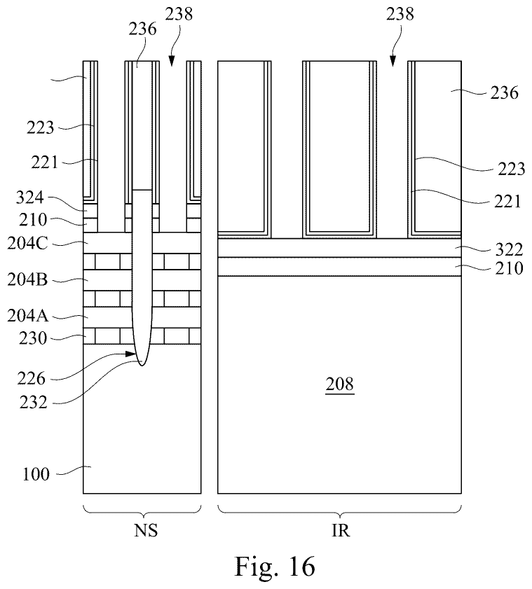

Reference is made to FIG. 16. FIG. 16 illustrates forming an interlayer dielectric (ILD) layer 236 over the source/drain regions 232 and between the first spacer layers 221 and the second spacer layers 223. FIG. 16 illustrates cross-sectional views of the nanostructure region NS and the isolation region IR along a longitudinal axis of the nanostructures 203.

As illustrated in FIG. 16, an ILD layer 236 is deposited over the structure illustrated in FIG. 15. The ILD layer 236 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) is disposed between the ILD layer 236 and the epitaxial source/drain regions 232, the masks 218, and the first spacers 221.

After the ILD layer 236 is formed, a planarization process, such as a CMP, may be performed to level the top surface of the ILD layer 236 with the top surfaces of the dummy gates 216 or the masks 218. The planarization process may also remove the masks 218 on the dummy gates 216, and portions of the first spacers 221 along sidewalls of the masks 218. After the planarization process, top surfaces of the dummy gates 216, the first spacers 221, and the ILD layer 236 are level within process variations. Accordingly, the top surfaces of the dummy gates 216 are exposed through the ILD layer 236. In some embodiments, the masks 218 may remain, in which case the planarization process levels the top surface of the ILD layer 236 with top surface of the masks 218 and the first spacers 221.

In some embodiments, after the ILD layer 236 is formed, the ILD layer 236 is etched back to fall below the dummy gates 216, and then a protective layer is formed over the ILD layer 236 and can serve to protect the underlying ILD layer 236 from potential loss or damage caused by the following MGEB process.

In FIG. 16, the dummy gates 216, and the masks 218 if present, are removed in one or more etching steps, so that gate trenches 238 are formed between corresponding gate spacers 221. In some embodiments, portions of the dummy gate dielectric layers 210 and the protection hard masks 324 in the gate trenches 238 are also be removed. In one or more embodiments, an oxidation treatment is performed to the protection hard masks 324, and the oxidation treatment to the protection hard masks 324 is controlled so that the protection hard masks 324 exposed from the first spacers 221 and the second spacers 223 on the nanostructures 204 is oxidized and the protection hard mask 322 on the STI region 208 is not oxidized. For example, the oxidation treatment to the protection hard masks 324 may include plasma oxidation treatment such as an anisotropic inductively coupled plasma (ICP) treatment with radical and noble gas to the protection hard masks 324. Reference is made to FIG. 14A, the protection hard masks 324 over the nanostructures 204 in the nanostructure regions NS is higher than the protection hard masks 322 over the STI region 208. Lifetime of the radical used in the ICP treatment to the protection hard masks 324 may be short, so that the radical used in the ICP treatment to the protection hard masks 324 would not achieve the protection hard masks 322 when the protection hard masks 324 is oxidized. In some embodiments, an operation pressure of the ICP oxidation treatment may be in a range from about 5 mTorr to about 30 mTorr. In some embodiments, an operation temperature may be in a range from about 250° C. to about 450° C. Therefore, the oxidized portion of the protection hard mask 324 and the dummy dielectric layers 210 exposed from the first spacers 221 can be removed. In some embodiments, the removal process to the dummy dielectric layers 210 and the protection hard masks 324 of oxide may include, for example, an oxide removal wet etching process using dilute hydrofluoric (dHF) acid.

As illustrated in FIG. 16, each gate trench 238 exposes and/or overlies portions of nanostructures 204, which will serve as channel regions in subsequently completed GAA-FETs. The nanostructures 204 serving as the channel regions are disposed between neighboring pairs of the epitaxial source/drain regions 232. During the removal, the dummy dielectric layers 210 and the protection hard masks 324 may be used as etch stop layers when the dummy gates 216 are etched. The dummy dielectric layers 210 and the protection hard masks 324 may protect the overlapping nanostructures 204C during removing the dummy gates 216, so that loss of the nanostructures 204C can be reduced.

In some embodiments, the dummy dielectric layers 210 may be oxide material such as silicon oxide and the STI region 208 may also include oxide material. In one or more embodiments of the present disclosure, the protection hard masks 322 are formed over the dummy dielectric layers 210 and the STI region 208, so that the protection hard masks 322 can protect the STI region 208 when forming the gate trenches 238. Therefore, selectively forming the protection hard masks 322 on the top surface of STI region 208 can reduce the risk of device degradation and metal gate line-to-line leakage, and it effective to prevent damage to the STI region 208 in replacement gate (RPG) loop and reduced the risk of device degradation and the metal gate line-to-line leakage can be reduced.

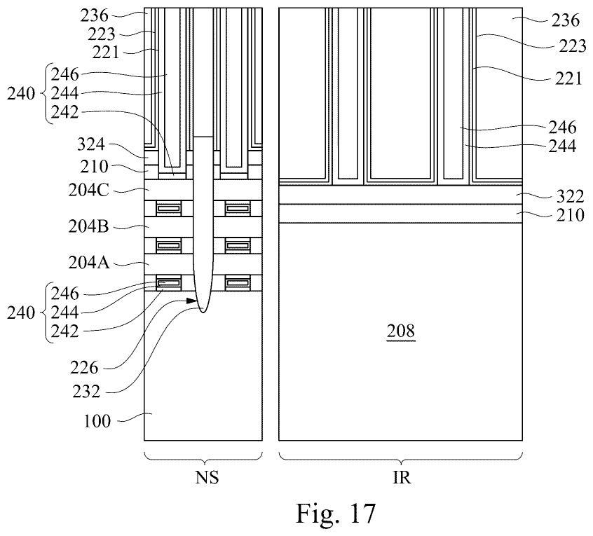

Continuing to FIG. 16, FIG. 17 illustrates forming replacement gate structures 240 in the gate trenches 238. FIG. 17 illustrates cross-sectional views of the nanostructure region NS and the isolation region IR along a longitudinal axis of the nanostructures 203.

In FIG. 17, replacement gate structures 240 are respectively formed in the gate trenches 238 to surround each of the nanosheets 204 suspended in the gate trenches 238. The gate structures 240 may be final gates of GAA FETs. The final gate structure may be a high-k/metal gate stack, however other compositions are possible. In some embodiments, each of the gate structures 240 forms the gate associated with the multi-channels provided by the plurality of nanosheets 204. For example, high-k/metal gate structures 240 are formed within the sheet-to-sheet spaces provided by the release of nanosheets 204. In various embodiments, the high-k/metal gate structure 240 includes an interfacial layer 242 formed around the nanosheets 204, a high-k gate dielectric layer 244 formed around the interfacial layer 242, and a gate metal layer 246 formed around the high-k gate dielectric layer 244 and filling a remainder of gate trenches 238. Formation of the high-k/metal gate structures 240 may include one or more deposition processes to form various gate materials, followed by a CMP process to remove excessive gate materials, resulting in the high-k/metal gate structures 240 having top surfaces level with a top surface of the protective layer 237. As illustrated in the cross-sectional view of FIG. 17, the high-k/metal gate structure 240 surrounds each of the nanosheets 204, and thus is referred to as a gate of a GAA FET.

In some embodiments, the interfacial layer 242 is silicon oxide formed on exposed surfaces of semiconductor materials in the gate trenches 238 by using, for example, thermal oxidation, chemical oxidation, wet oxidation or the like. As a result, surface portions of the nanosheets 204 exposed in the gate trenches 238 are oxidized into silicon oxide to form interfacial layer 242.

In some embodiments, the gate metal layer 246 includes one or more metal layers. For example, the gate metal layer 246 may include one or more work function metal layers stacked one over another and a fill metal filling up a remainder of gate trenches 238. The one or more work function metal layers in the gate metal layer 246 provide a suitable work function for the high-k/metal gate structures 240.

As illustrated in FIG. 17, a semiconductor device 200′ is provided. Difference between the semiconductor device 200 as illustrated in FIG. 11 and the semiconductor device 200′ as illustrated in FIG. 17 may include that dummy dielectric layer 210 remains over the SIT region 208 and the nanostructures 204C. Difference between the semiconductor device 200 as illustrated in FIG. 11 and the semiconductor device 200′ as illustrated in FIG. 17 may further include the protection hard mask 322 and 324 over the dummy dielectric layer 210. As illustrated in FIG. 17, the dummy dielectric layers 210 and the protection hard mask 324 may be collectively referred as low-k spacer between the first spacers 221 and the nanostructures 204C.

According to one or more embodiments of the present disclosure, a method of forming a semiconductor device includes a number of operations. A first semiconductor fin and a second semiconductor fin are formed over a substrate. An isolation region is formed between the first semiconductor fin and the second semiconductor fin. A first passivation layer is formed over the isolation region. A gate structure is formed over the first passivation layer. In one or more embodiments of the present disclosure, the method further includes forming a dielectric layer over the isolation region, wherein the first passivation layer is formed over the dielectric layer. In some embodiments, the method further includes oxidizing the first passivation layer. In one or more embodiments of the present disclosure, the passivation layer is a carbon-containing layer. In one or more embodiments of the present disclosure, the method further includes a number of operations. Second passivation layers are formed over the first and second semiconductor fins. A sacrificial layer is formed over the first and second passivation layers. A planarization process is performed to the second passivation layers, the sacrificial layer and the first and second semiconductor fins. In some embodiments, the first and second passivation layers are carbon-containing layers. In some embodiments, the first and second passivation layers are formed by a physical vapor deposition process. In some embodiments, the first and second passivation layers are formed by an plamsa-enhanced atomic layer deposition process. In some embodiments, a thickness of topmost nanostructures of the first and second semiconductor fins is reduced during performing the planarization process. In one or more embodiments of the present disclosure, the method further includes forming a spacer layer over first passivation layer on the isolation region and the first and second semiconductor fins.

According to one or more embodiments of the present disclosure, a method of forming a semiconductor device includes a number of operations. A semiconductor fin including first nanostructures and second nanostructures alternating with the first nanostructures is formed. A shallow trench isolation (STI) region is formed and abuts a lower portion of the semiconductor fin. A dielectric layer is formed and has a first portion over the STI region and a second portion over a sidewall of the semiconductor fin. A carbon-containing mask layer is formed over the dielectric layer. A first portion of the carbon-containing mask layer is oxidized on the semiconductor fin. The oxidized first portion of the carbon-containing mask layer and the dielectric layer over the semiconductor fin are removed to expose the sidewall of the semiconductor fin, wherein the dielectric layer over the STI region is covered by a second portion of the carbon-containing mask layer. The first nanostructures are replaced with a gate structure wrapping around the second nanostructures, while the dielectric layer and the second portion of the carbon-containing mask layer remain over the STI region. In one or more embodiments of the present disclosure, the first portion of the carbon-containing mask layer on the semiconductor fin is oxidized by an inductively coupled plasma treatment. In one or more embodiments of the present disclosure, the carbon-containing mask layer is formed by a plamsa-enhanced atomic layer deposition process. In one or more embodiments of the present disclosure, the carbon-containing mask layer is formed by a physical vapor deposition process. In one or more embodiments of the present disclosure, the carbon-containing mask layer includes SiCₓ, SiOₓC_{y}N_{1-x-y} or SiOCₓ.

According to one or more embodiments of the present disclosure, a semiconductor device includes a shallow trench isolation (STI) region, a first passivation layer, a first gate structure, a transistor, a gate spacer and a second passivation layer. The STI region is in a substrate. The first passivation layer is over the STI region. The first gate structure is over the STI region and spaced apart from the STI region by the first passivation layer. The transistor is over the substrate. The transistor includes a second gate structure and source/drain regions on opposite sides of the second gate structure. A gate spacer is formed on a sidewall of the second gate structure. A second passivation layer is formed under a bottom surface of the gate spacer. The second passivation layer is formed of a same material composition as the first passivation layer. In one or more embodiments of the present disclosure, the semiconductor device further includes a first oxide layer between the STI region and the first passivation layer. In some embodiments, the semiconductor device further includes a second oxide layer under the second passivation layer. The second oxide layer is formed of a same material composition as the first oxide layer. In some embodiments, the source/drain regions of the transistor are in contact with sidewalls of the gate spacer, the second passivation layer and the second oxide layer. In one or more embodiments of the present disclosure, the first passivation layer includes SiCₓ, SiOₓC_{y}N_{1-x-y} or SiOCₓ.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first semiconductor fin and a second semiconductor fin over a substrate;
forming an isolation region between the first semiconductor fin and the second semiconductor fin;
forming a first passivation layer over the isolation region; and
forming a gate structure over the first passivation layer.

2. The method of claim 1, further comprising:
forming a dielectric layer over the isolation region, wherein the first passivation layer is formed over the dielectric layer.

3. The method of claim 2, further comprising:
oxidizing the first passivation layer.

4. The method of claim 1, wherein the passivation layer is a carbon-containing layer.

5. The method of claim 1, further comprising:
forming second passivation layers over the first and second semiconductor fins;
forming a sacrificial layer over the first and second passivation layers; and
performing a planarization process to the second passivation layers, the sacrificial layer and the first and second semiconductor fins.

6. The method of claim 5, wherein the first and second passivation layers are carbon-containing layers.

7. The method of claim 5, wherein the first and second passivation layers are formed by a physical vapor deposition process.

8. The method of claim 5, wherein the first and second passivation layers are formed by a plamsa-enhanced atomic layer deposition process.

9. The method of claim 5, wherein a thickness of topmost nanostructures of the first and second semiconductor fins is reduced during performing the planarization process.

10. The method of claim 1, further comprising:
forming a spacer layer over first passivation layer on the isolation region and the first and second semiconductor fins.

11. A method comprising:
forming a semiconductor fin comprising first nanostructures and second nanostructures alternating with the first nanostructures;
forming a shallow trench isolation (STI) region abutting a lower portion of the semiconductor fin;
forming a dielectric layer having a first portion over the STI region and a second portion over a sidewall of the semiconductor fin;
forming a carbon-containing mask layer over the dielectric layer;
oxidizing a first portion of the carbon-containing mask layer on the semiconductor fin;
removing the oxidized first portion of the carbon-containing mask layer and the dielectric layer over the semiconductor fin to expose the sidewall of the semiconductor fin, wherein the dielectric layer over the STI region is covered by a second portion of the carbon-containing mask layer; and
replacing the first nanostructures with a gate structure wrapping around the second nanostructures, while the dielectric layer and the second portion of the carbon-containing mask layer remain over the STI region.

12. The method of claim 11, wherein the first portion of the carbon-containing mask layer on the semiconductor fin is oxidized by an inductively coupled plasma treatment.

13. The method of claim 11, wherein the carbon-containing mask layer is formed by a plamsa-enhanced atomic layer deposition process.

14. The method of claim 11, wherein the carbon-containing mask layer is formed by a physical vapor deposition process.

15. The method of claim 11, wherein the carbon-containing mask layer comprises SiCₓ, SiOₓC_{y}N_{1-x-y} or SiOCₓ.

16. A semiconductor device comprising:
a shallow trench isolation (STI) region in a substrate;
a first passivation layer over the STI region;
a first gate structure over the STI region and spaced apart from the STI region by the first passivation layer;
a transistor over the substrate, the transistor comprising a second gate structure and source/drain regions on opposite sides of the second gate structure;
a gate spacer on a sidewall of the second gate structure; and
a second passivation layer under a bottom surface of the gate spacer, wherein the second passivation layer is formed of a same material composition as the first passivation layer.

17. The semiconductor device of claim 16, further comprising:
a first oxide layer between the STI region and the first passivation layer.

18. The semiconductor device of claim 17, further comprising:
a second oxide layer under the second passivation layer, wherein the second oxide layer is formed of a same material composition as the first oxide layer.

19. The semiconductor device of claim 18, wherein the source/drain regions of the transistor are in contact with sidewalls of the gate spacer, the second passivation layer and the second oxide layer.

20. The semiconductor device of claim 16, wherein the first passivation layer comprises SiCₓ, SiOₓC_{y}N_{1-x-y} or SiOCₓ.
